(19) United States
(12) Patent Application Publication
(10) Pub. No.: US 2015/0170747 A1
(43) Pub. Date: Jun. 18, 2015

(54) METHOD AND SYSTEM FOR PROGRAMMING A MULTI-BIT PER CELL NON-VOLATILE MEMORY

(71) Applicant: SKYMEDI CORPORATION, Hsinchu City (TW)

(72) Inventors: Po-Yen Liu, Hsinchu City (TW); Che-Wei Chang, Hsinchu City (TW)

(73) Assignee: SKYMEDI CORPORATION, Hsinchu City (TW)

(21) Appl. No.: 14/109,923

(22) Filed: Dec. 17, 2013

(51) Int. Cl. G11C 16/10

(52) U.S. Cl. CPC G11C 16/107

(57) ABSTRACT

A system and method for programming a multi-bit per cell non-volatile memory with padding data is disclosed to program at least one less-significant-bit (LSB) page with padding data while programming host data in the multi-bit per cell non-volatile memory, in a manner such that a more-significant-bit (MSB) page corresponding to each LSB page programmed with host data of the same write command is programmed with host data.

### BACKGROUND OF THE INVENTION

1. Field of the Invention

The disclosure generally relates to a non-volatile memory, and more particularly to a method and system for programming a multi-bit per cell non-volatile memory with padding data.

2. Description of Related Art

A flash memory is a non-volatile solid state memory device that can be electrically erased and programmed. Advantages of using flash memory over other memories include, for example, low power, non-volatile storage, high performance, physical stability, and portability.

The flash memory has been widely adopted in electronic devices, particularly portable electronic devices, such as digital cameras, personal digital assistants (PDAs), MPEG-1 or MPEG-2 Audio Layer III (commonly referred to as MP3) players, mobile phones, and tablet computers. The electronic devices may be implemented using a variety of interface protocols such as Secure Digital (SD), microSD (μSD), embedded SD (eSD), embedded MultiMediaCard (eMMC), Universal Serial Bus (USB), Peripheral Component Interconnect Express (PCIe), and Serial Advanced Technology Attachment (SATA).

Conventional flash memory, commonly referred to as single-bit per cell flash memory, stores a single bit of information in each memory cell such that each memory cell can be programmed to assume two possible states. Modern flash memory, commonly referred to as multi-bit per cell flash memory, is capable of storing two or more bits of information in each memory cell such that each memory cell can be programmed to assume more than two possible states, therefore increasing memory capacity or reducing manufacturing cost.

A logical addressing and translation scheme is commonly used for specifying the location of data stored in the flash memory, which is composed of a number of physical data blocks. Accordingly, each physical data block may be shared among a number of logical units. For a multi-bit per cell flash memory, when one logical unit associated with one command is corrupted, another logical unit associated with another command may probably be damaged. FIG. 1 shows an exemplary data block of a two-bit per cell flash memory, which is composed of a number of data pages. Each word line corresponds to a pair of a least-significant-bit (LSB) page and a most-significant-bit (MSB) page as shown. The sequence numbers denote a programming sequence. When pages 8 and 9 associated with a logical unit are being programmed but are corrupted, for example, due to a power failure, corresponding previously programmed pages 2 and 3 associated with another logical unit may be damaged.

A need has thus arisen to propose a novel and effective scheme to prevent interference with other logical units in cases of programming failure.

### SUMMARY OF THE INVENTION

In view of the foregoing, it is an object of the embodiment of the present invention to provide a system and method for programming a non-volatile memory with padding data in an effective manner with high performance and low write amplification.

According to one embodiment, a write command with host data is received, and at least one less-significant-bit (LSB) page is programmed with padding data while programming the host data in the multi-bit per cell non-volatile memory. The at least one LSB page is programmed in a manner such that an MSB page corresponding to each LSB page programmed with host data of the same write command is programmed with host data.

### BRIEF DESCRIPTION OF THE DRAWINGS

FIG. 1 shows an exemplary data block of a two-bit per cell flash memory;

FIG. 2 demonstrates a first scheme for preventing interference with other logical units in case of programming failure;

FIG. 3 demonstrates a second scheme for preventing interference with other logical units in case of programming failure;

FIGS. 4A to 4C demonstrate a third scheme for preventing interference with other logical units in case of programming failure;

FIG. 5 shows a block diagram illustrating a memory system according to one embodiment of the present invention;

FIG. 6 shows a flow diagram illustrating a method for programming a multi-bit per cell non-volatile memory with padding data according to one embodiment of the present invention;

FIG. 7A to FIG. 7F show exemplary data blocks of padding dummy data according to the flow diagram of FIG. 6;

FIG. 8 shows a flow diagram illustrating a method for programming a multi-bit per cell non-volatile memory with padding data according to a modified embodiment of the present invention;

FIGS. 9A to 9C show an example illustrating padding GC old data and dummy data in sequence according to the flow diagram of FIG. 8; and

FIG. 10 shows a flow diagram illustrating a method for programming a multi-bit per cell non-volatile memory with padding data according to another modified embodiment of the present invention.

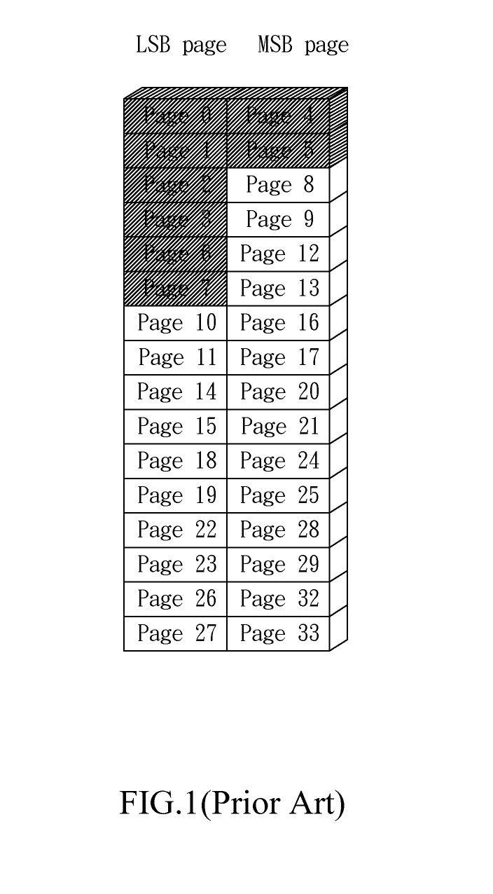

### DETAILED DESCRIPTION OF THE INVENTION

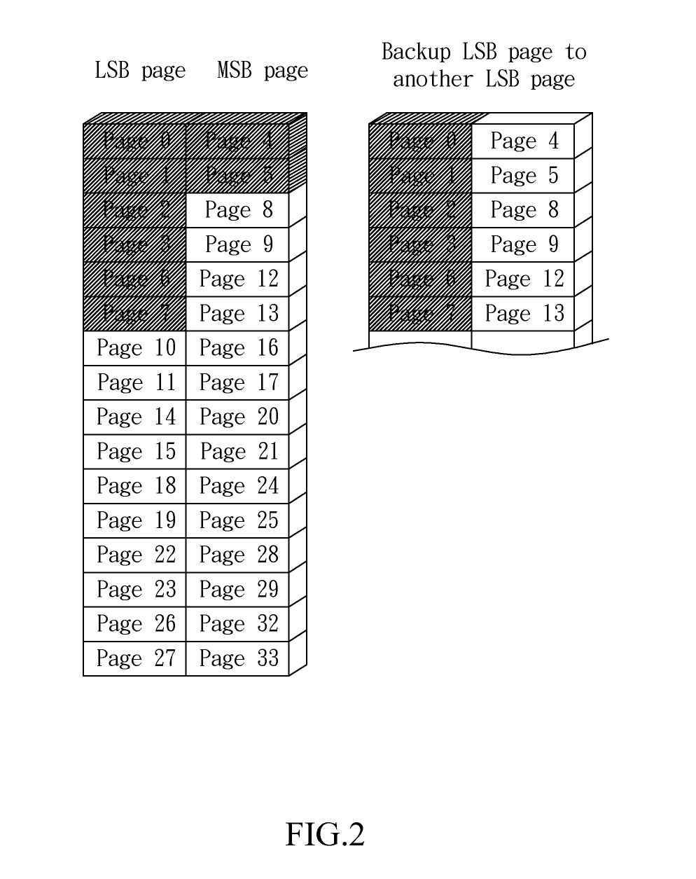

Some schemes have been proposed to prevent interference with other logical units in cases of programming failure such as power failure. FIG. 2 demonstrates a first scheme, which is referred to as LSB page backup scheme in the specification. The sequence numbers denote a probable, but not exclusive, programming sequence. In this scheme, before MSB pages are programmed in a target data block, data of corresponding LSB pages are backed up in LSB pages of an auxiliary data block.

For example, as demonstrated in FIG. 2, before MSB pages 4 and 5 are programmed in a (left-hand) target data block, data of corresponding LSB pages 0 and 1 is backed up in LSB pages 0 and 1 of a (right-hand) auxiliary data block. Similarly, before MSB pages 8 and 9 are programmed in the (left-hand) target data block, data of corresponding LSB pages 2 and 3 is backed up in LSB pages 2 and 3 of the (right-hand) auxiliary data block. The first scheme, disadvantageously, requires the extra auxiliary data block, and its correspondingly required programming time, to back up data of LSB pages, therefore resulting in high write amplification (i.e., the actual amount of physical data written is a multiple of the logical amount intended to be written) and low performance.

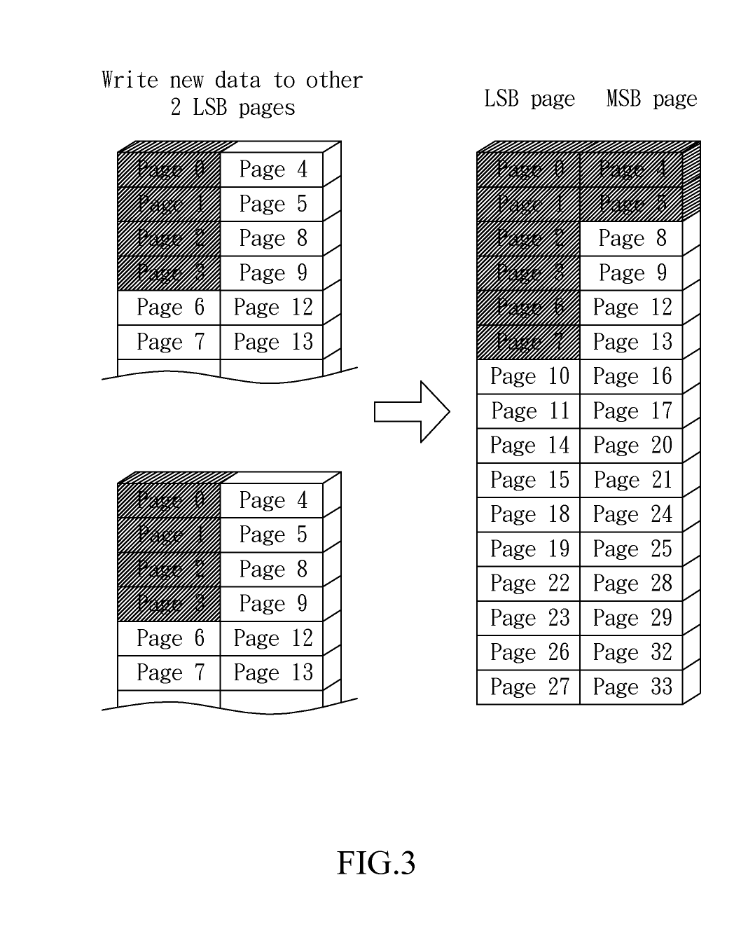

FIG. 3 demonstrates a second scheme, which is referred to as first write LSB pages scheme in the specification. In this scheme, before data is programmed in a target data block, all data is temporarily stored in LSB pages of auxiliary data blocks; and the whole lot of the temporarily stored data of the LSB pages is then programmed as a whole in (LSB pages and MSB pages of) the target data block.

For example, as demonstrated in FIG. 3, before data is programmed in a (right-hand) target data block, all data is temporarily stored in LSB pages of two (left-hand) auxiliary data blocks; and the whole lot of the temporarily stored data of the LSB pages is then programmed as a whole in LSB pages and MSB pages of the (right-hand) target data block. The second scheme, disadvantageously, requires the extra auxiliary data blocks, and their correspondingly required programming time, to temporarily store data, therefore resulting in high write amplification and low performance.

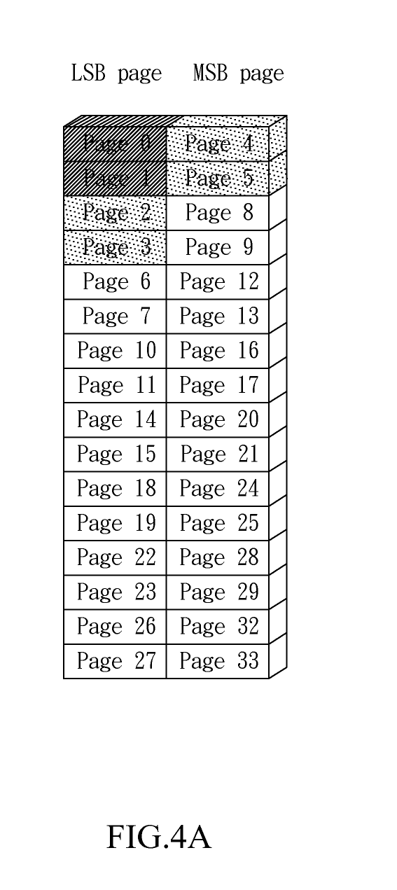

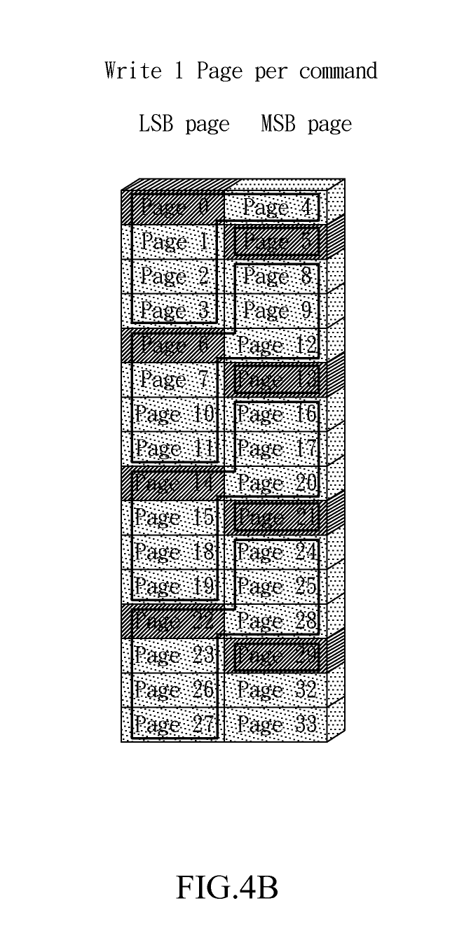

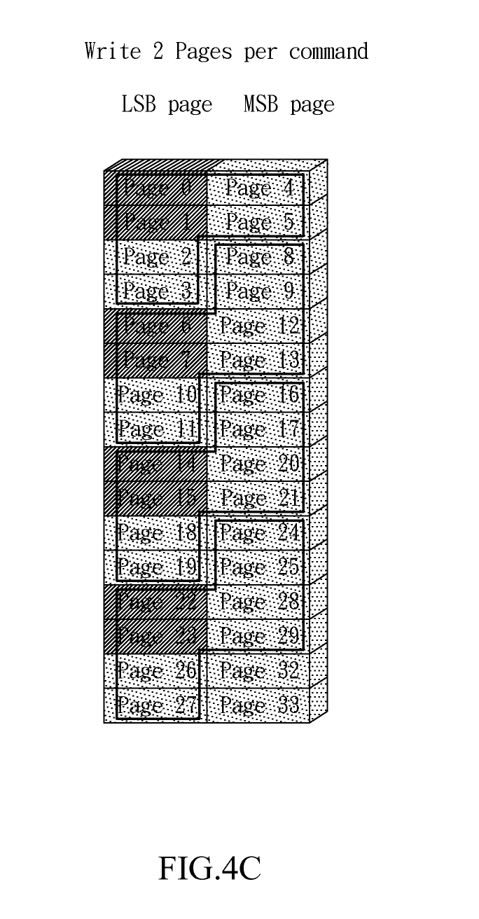

FIGS. 4A to 4C demonstrate a third scheme, which is referred to as pad page after write scheme in the specification. In this scheme, after page or pages are programmed in a target data block, dummy data is padded adjacent with programmed page(s) in the target data block. Generally speaking, dummy data is padded in at least one LSB page, at least one MSB page or both in a manner such that each LSB page programmed with host data of a write command received from a host is protected with corresponding MSB page programmed with dummy data, and is therefore not vulnerable to succeeding write command.

For example, as demonstrated in FIG. 4A, after (shaded) pages 0 and 1 are programmed with host data in a data block, (dotted) pages 2-5 are programmed with dummy data in the data block. The third scheme does not require extra auxiliary data block to back up data of LSB pages as in the first scheme, and does not require extra auxiliary data blocks to temporarily store data as in the second scheme. The third scheme requires padding dummy data with an amount depending on an amount of programmed host data. However, the storage space and required time being wasted may, in a worse case, even be greater than that in the first scheme. FIG. 4B exemplifies a third scheme, in which one page (e.g., page 0) is programmed with host data per command, followed by padding dummy data in pages (e.g., pages 1-4. Specifically, page 0 of a first command is programmed, followed by padding dummy data in pages 1-4. Next, page 5 of a second command is programmed without padding dummy data. Afterwards, page 6 of a third command is programmed, followed by padding dummy data in pages 7-12. FIG. 4C further exemplifies a third scheme, in which two pages (e.g., pages 0 and 1) are programmed with host data per command, followed by padding dummy data in pages (e.g., pages 2-5). Specifically, pages 0-1 of a first command are programmed with host data, followed by padding dummy data in pages 2-5. Next, pages 6-7 of a second command are programmed with host data, followed by padding dummy data in pages 8-13. Afterwards, pages 14-15 of a third command are programmed with host data, followed by padding dummy data in pages 16-21. As demonstrated in FIGS. 4B and 4C, the padding dummy data has an amount three times the programmed host data.

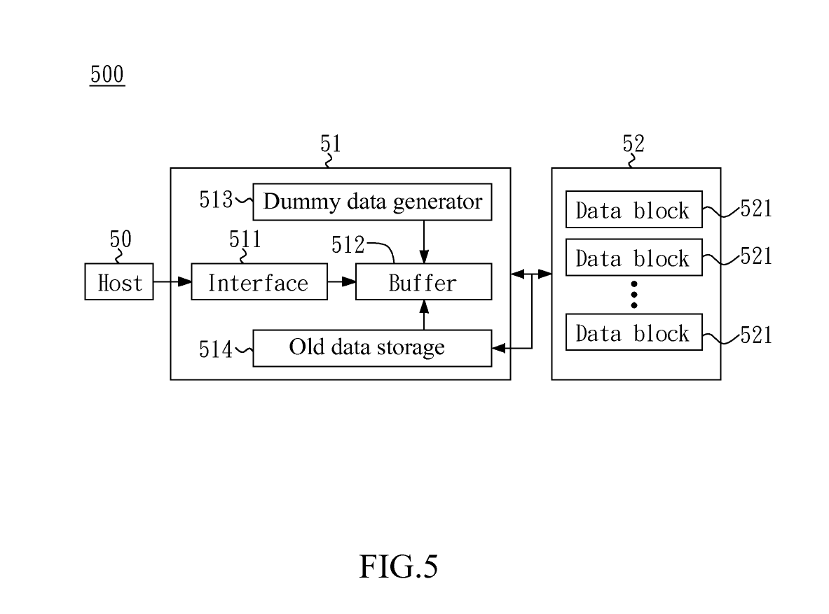

FIG. 5 shows a block diagram illustrating a memory system 500 that is capable of effectively preventing interference with other logical units in case of programming failure according to one embodiment of the present invention. In the embodiment, the memory system 500 includes a controller 51 disposed between a host 50 (e.g., a computer) and a non-volatile memory 52. The non-volatile memory 52, such as a multi-bit per cell flash memory, may include at least a number of (multi-bit per cell) data blocks 521. The non-volatile memory 52 may further include single-bit per cell data blocks.

The controller 51 of the embodiment may include an interface 511 electrically coupled to, and being communicating with, the host 50. The interface 511 may be compliant with a protocol such as SD, SSD, eSD, eMMC, USB, PCIe, or SATA. The controller 51 may also include a buffer 512 configured to temporarily store data while the data is being moved to/from the non-volatile memory 52. The controller 51 may further include a dummy data generator 513 configured to generate dummy data; and an old data storage 514 configured to store old data retrieved from (multi-bit or single-bit per cell) data blocks 521. It is noted that the old data storage 514 may be a part of, and integrated with, the buffer 512. In the embodiment, the term “old data” means data that already exists in the non-volatile memory 52 before a current command with host data is received.

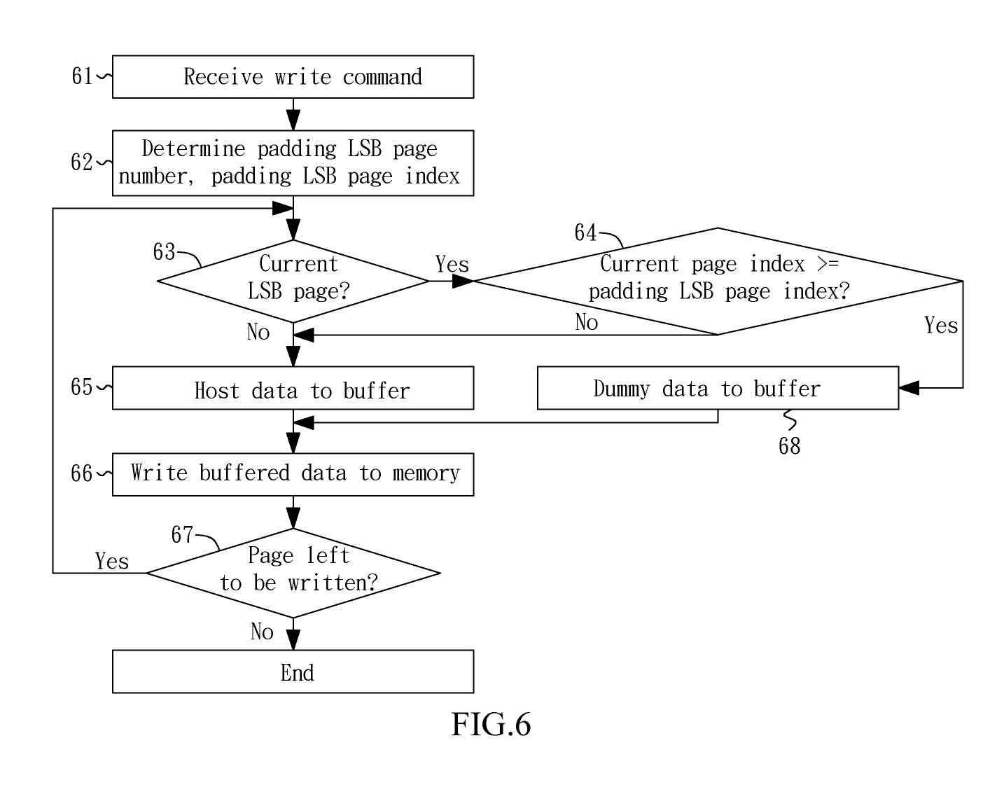

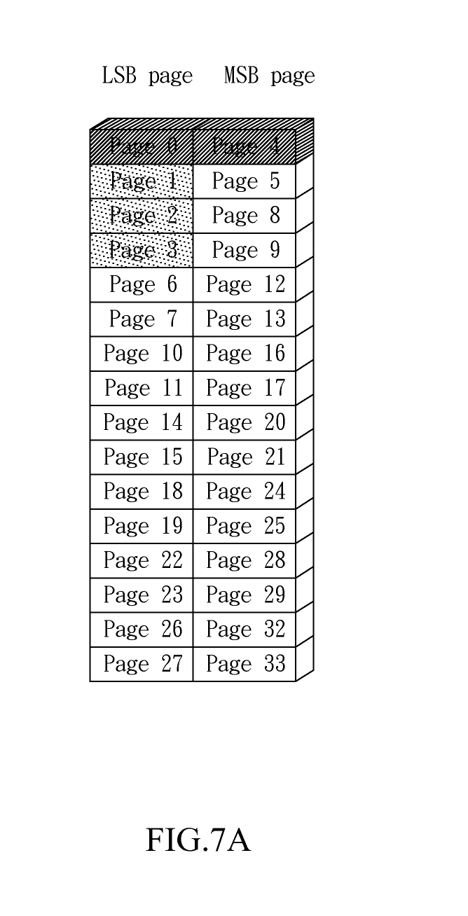

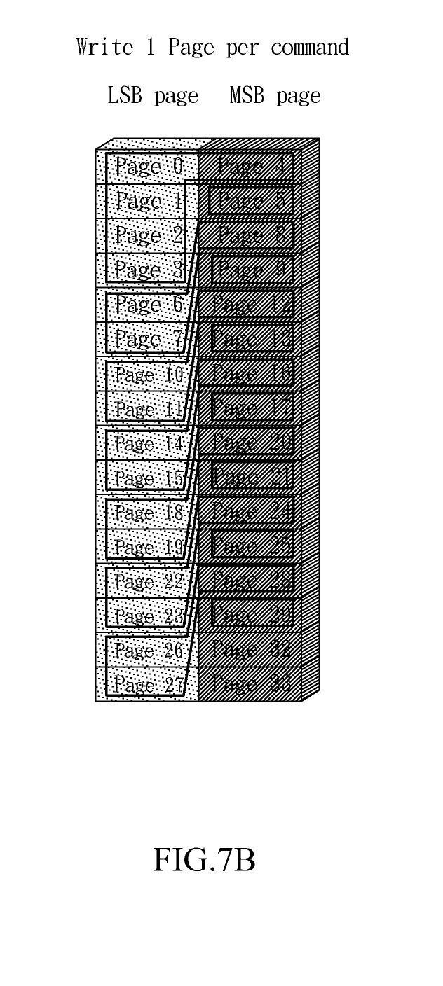

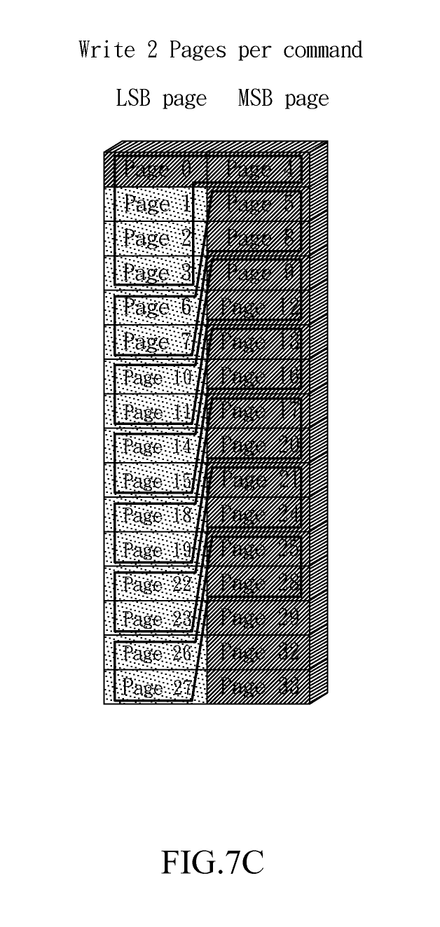

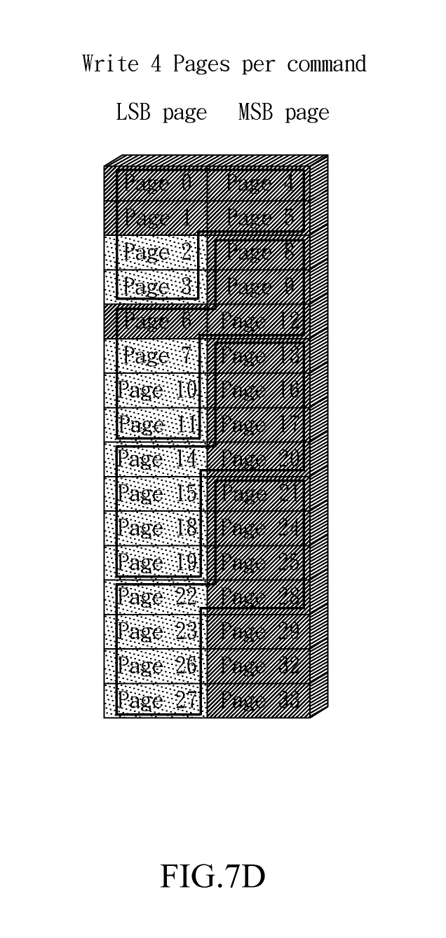

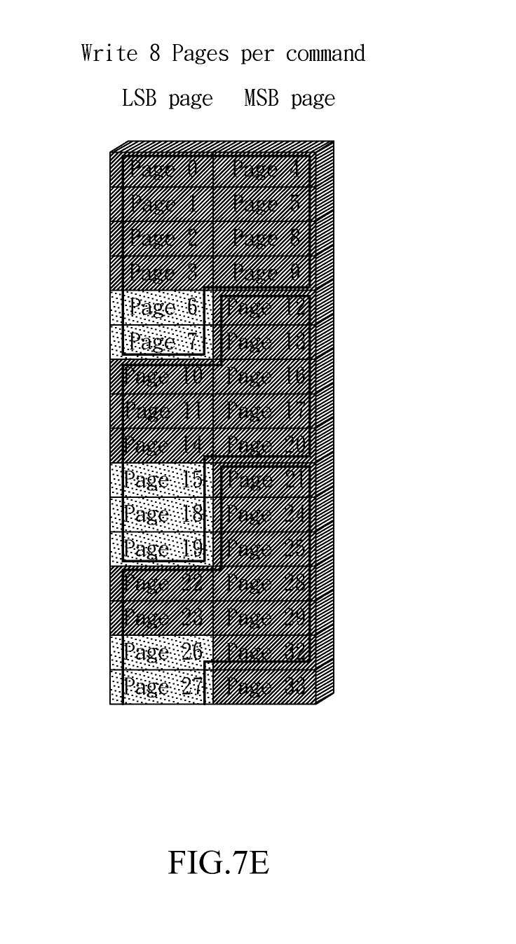

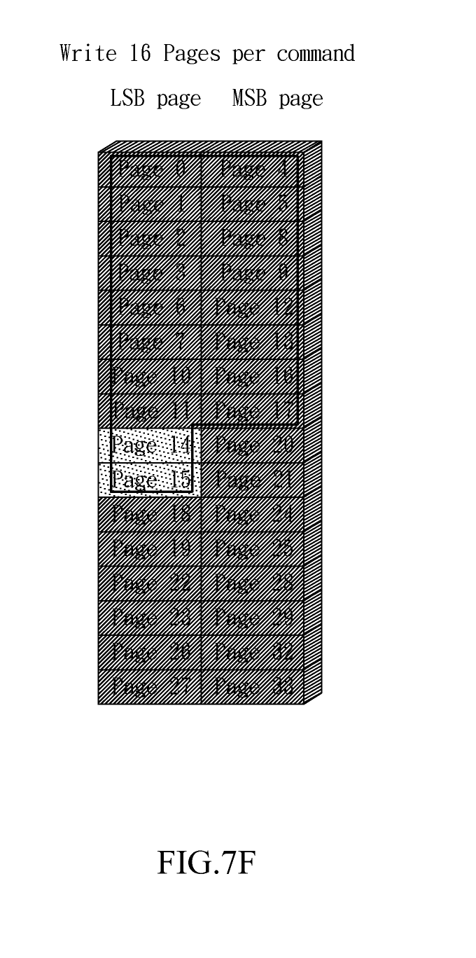

FIG. 6 shows a flow diagram illustrating a method for programming a multi-bit per cell non-volatile memory 52 with padding data to effectively prevent interference with other logical units in case of programming failure according to one embodiment of the present invention. FIG. 7A shows an exemplary data block accompanying the flow diagram of FIG. 6. Although a two-bit per cell non-volatile memory (e.g., flash memory) is exemplified in the embodiment, it is appreciated that the embodiment may be generally adapted to a multi-bit per cell non-volatile memory. Generally speaking, the term “least-significant-bit” may be replaced or interchanged with a less-significant-bit, and the term “most-significant-bit” may be replaced or interchanged with a more-significant-bit. Regarding a three-bit per cell non-volatile memory, for example, each word line corresponds to a least-significant-bit (LSB) page, a center-significant-bit (CSB) page and a most-significant-bit (MSB) page. The LSB page and the CSB page may be regarded as less-significant-bit pages, and the MSB page may be regarded as a more-significant-bit page.

In step 61, a write command issued from the host 50 is received by the controller 51. According to information (such as host data length and written position) derived and translated from the received write command, the controller 51, in step 62, may determine a padding LSB (least-significant-bit) page number (i.e., an amount of padding LSB pages to be programmed) and a padding LSB page index (i.e., a position at which the padding LSB pages begin). As exemplified in FIG. 7A, the controller 51 receives a write command with information of the host data length of two pages and the written position beginning at page 0. According to the information of the write command, the controller 51 then determines the padding LSB page number to be three and the padding LSB page index to begin at page 1. Details of determining the padding LSB page number and the padding LSB page index in step 62 will be demonstrated and exemplified later in this specification. Generally speaking, according to one aspect of the embodiment, only LSB pages are padded. Moreover, the MSB page corresponding to each LSB page programmed with host data of the same write command should also be programmed with host data such that the programmed LSB page is not vulnerable to succeeding write command, thereby resulting in a pair or a group of pages on the same word line programmed with host data.

Afterwards, in step 63, the controller 51 checks whether the current programming page (e.g., page 0) is an LSB page. If yes, it is further checked, in step 64, whether an index or position (e.g., 0) of the current (LSB) programming page is greater than or equal to the padding LSB page index (e.g., 1). If no, the flow goes to step 65, by which host data is moved to the buffer 512. Subsequently, in step 66, the buffered host data (in the buffer 512) is written to the non-volatile memory 52, thereby programming (dashed) page 0 with host data in the data block shown in FIG. 7A.

As there is still one page left to be written, as determined in step 67, the flow goes back to step 63. In step 63, it is checked that the current programming page (e.g., page 1) is an LSB page, and in step 64, it is checked that an index (e.g., 1) of the current (LSB) programming page is equal to the padding LSB page index (e.g., 1), the flow goes to step 68, by which dummy data provided from the dummy data generator 513 is moved to the buffer 512. Subsequently, in step 66, the buffered dummy data (in the buffer 512) is written to the non-volatile memory 52, thereby programming (dotted) page 1 with dummy data.

The flow is repeatedly performed until no page left to be written, as determined in step 67. As a result shown in FIG. 7A, two (shaded) data pages 0 and 4 are programmed with host data in the data block, and three (dotted) padding LSB pages 1, 2, and 3 are programmed with dummy data.

FIG. 7B to FIG. 7F show further examples of padding dummy data according to the flow diagram of FIG. 6. Specifically, one page per command is written as demonstrated in FIG. 7B, two pages per command are written as demonstrated in FIG. 7C, four pages per command are written as demonstrated in FIG. 7D, eight pages per command are written as demonstrated in FIG. 7E, and sixteen pages per command are written as demonstrated in FIG. 7F.

In the following paragraph, the determination of the padding LSB page number and the padding LSB page index in step 62 is specifically demonstrated. Referring to FIG. 7A, for example, it is first determined that there are two pages of host data to be written. Accordingly, two pages (e.g., page 0 and page 1) are extended. Next, it is determined whether the two extended pages (i.e., page 0 and page 1) hit LSB page. More pages are extended in the same manner until the extended pages (e.g., page 4 and page 5) no longer hit LSB page. At this time, pages composed of host data should be as paired as possible (as exemplified by page 0 and page 4 in FIG. 7A); otherwise, pages composed of host data are arranged in MSB pages (as exemplified by page 4 in FIG. 7B). After the pages composed of host data are determined, extended pages not allocated with host data are therefore determined as padding LSB pages, according to which the padding LSB page number and the padding LSB page index may thus be ascertained.

Compared with the third scheme (i.e., pad page after write scheme) discussed above, the embodiment according to FIG. 6 pads only LSB pages, while both the LSB pages and the MSB pages may be padded in the third scheme. Moreover, the embodiment may pad dummy data before or after programming the host data, while the third scheme pad dummy data after programming the host data. Comparing FIGS. 7A-7F with FIGS. 4A-4C, the embodiment has a write amplification lower than the third scheme.

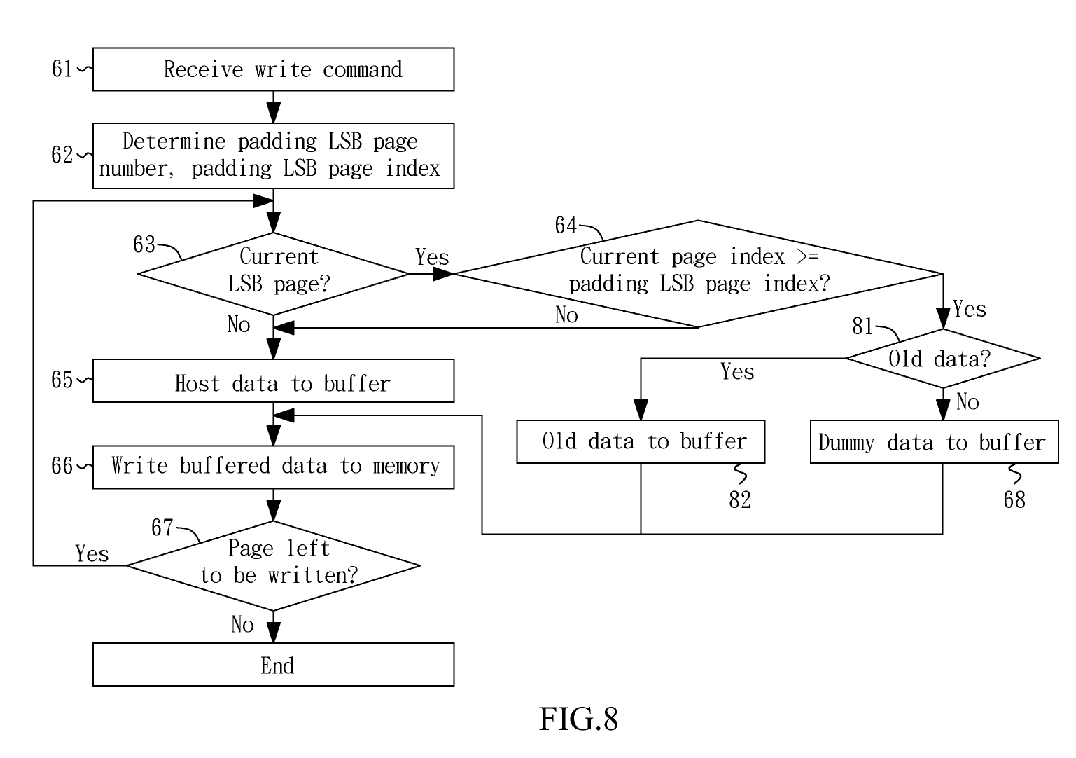

FIG. 8 shows a flow diagram illustrating a method for programming a non-volatile memory 52 with padding data according to a modified embodiment of the present invention. The flow diagram of FIG. 8 is similar to that of FIG. 6 with the difference that step 81 is inserted between step 64 and step 68. In step 81, the controller 51 checks whether programmed block contains old data on which garbage collection (GC) will be performed. If yes, the old data is moved to the buffer 512 in step 82, followed by writing the buffered data to the non-volatile memory 52. As a result, old data is programmed in the embodiment of FIG. 8, in stead of padding dummy data in the embodiment of FIG. 6. As fewer dummy data is padded, the embodiment of FIG. 8 has a higher performance than the embodiment of FIG. 6. Generally speaking, in the specification, either the dummy data or the old data may be referred to as the padding data.

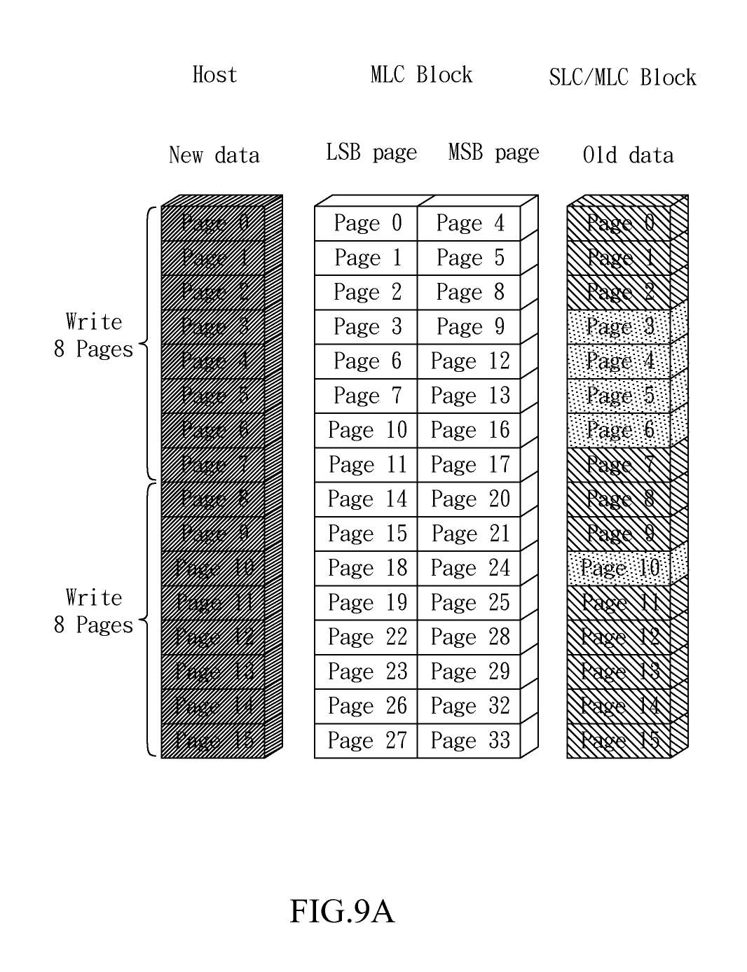

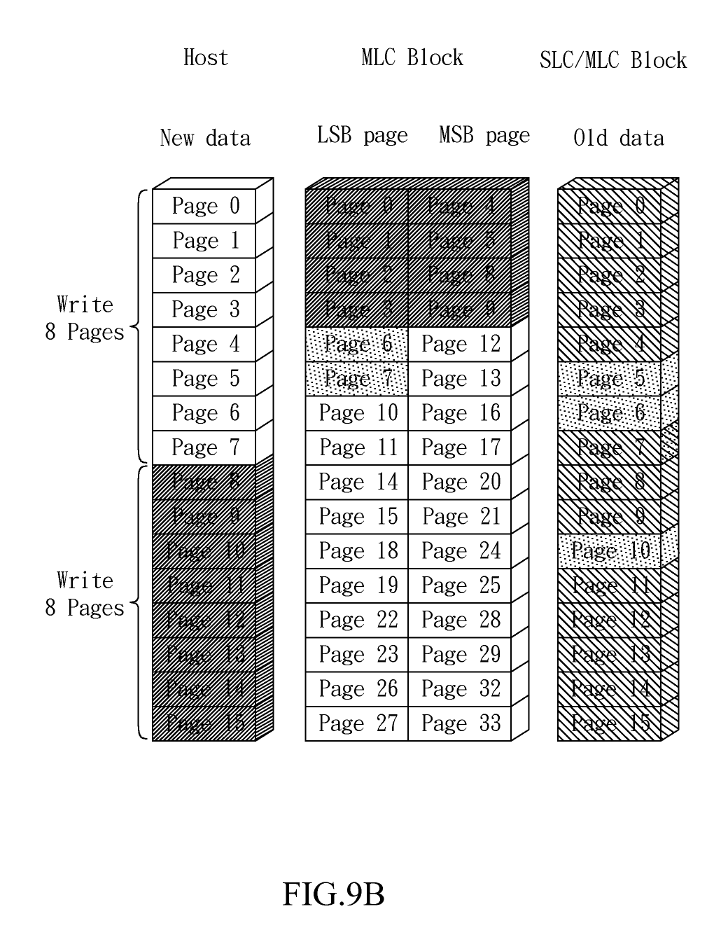

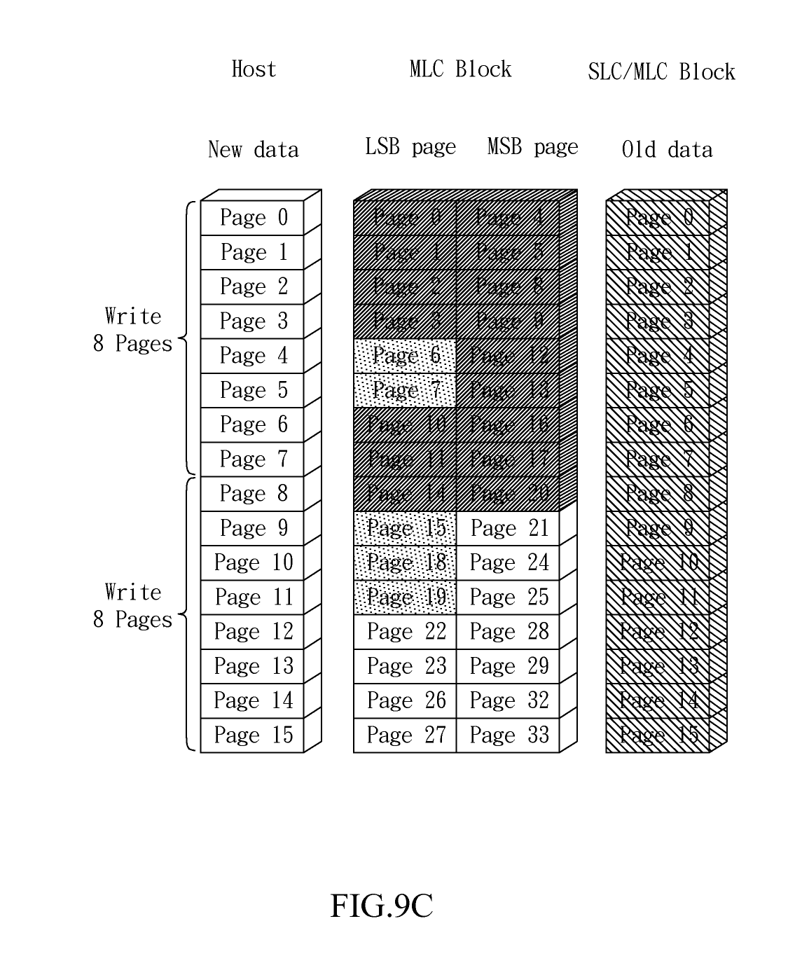

FIGS. 9A to 9C show an example illustrating padding GC old data and dummy data in sequence according to the flow diagram of FIG. 8. As demonstrated in FIG. 9A, (shaded) eight pages per command are twice written from a host 50 to a non-volatile memory 52 (e.g., a multi-level cell (MLC) data block) with (dotted) old data to be garbage collected from an MLC or single-level cell (SLC) data block. As shown in FIG. 9B, in the MLC block, eight (shaded) pages 0-5 and 8-9 are programmed with host data and two (dotted) pages 6-7 are programmed with old data. As shown in FIG. 9C, in the MLC block, eight (shaded) pages 10-14, 16-17 and 20 are further programmed with host data, one (dotted) page 15 is programmed with old data, and two (dotted) pages 18-19 are programmed with dummy data.

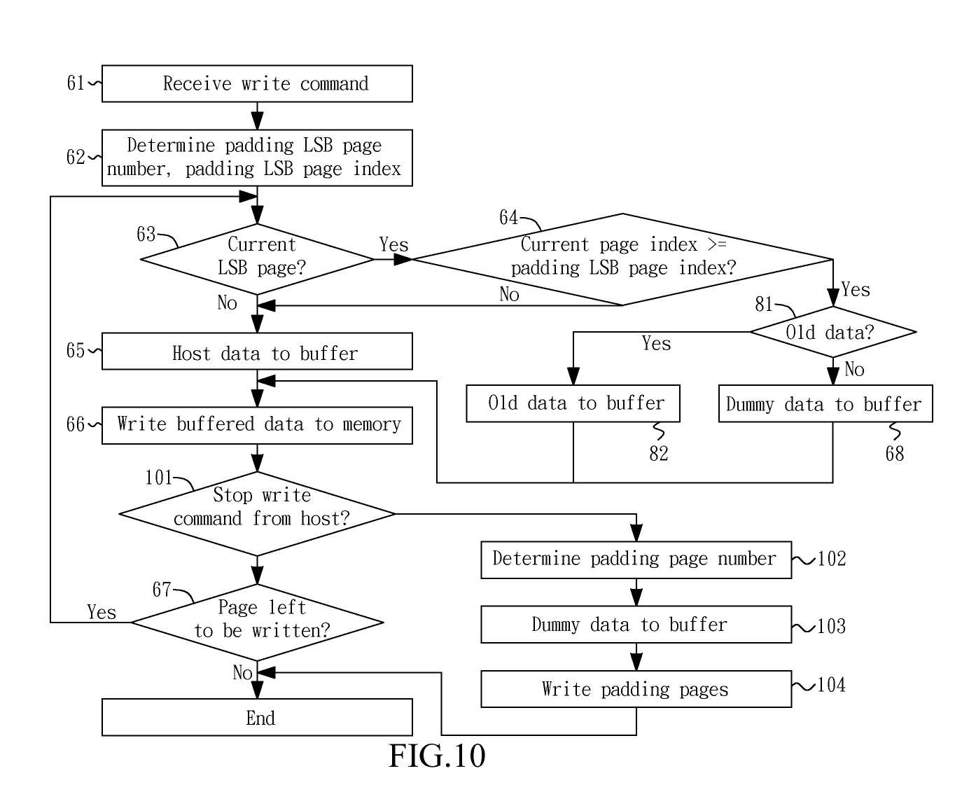

FIG. 10 shows a flow diagram illustrating a method for programming a non-volatile memory 52 with padding data according to another modified embodiment of the present invention. The flow diagram of FIG. 10 is similar to that of FIG. 8 with the difference that step 101 is inserted between step 66 and step 67. In step 101, the controller 51 checks whether a stop write command is issued from the host 50. If yes, the third scheme is performed. Specifically, in step 102, padding page number is determined; in step 103, move dummy data to the buffer 512; and in step 104, padding (LSB and MSB) pages are programmed according to the third scheme.

It is appreciated that the programming sequence exemplified above is one of probable programming sequences, and the embodiments demonstrated above may be well adapted to other programming sequences.

Although specific embodiments have been illustrated and described, it will be appreciated by those skilled in the art that various modifications may be made without departing from the scope of the present invention, which is intended to be limited solely by the appended claims.

What is claimed is:

1. A method for programming a multi-bit per cell non-volatile memory with padding data, comprising:
receiving a write command with host data; and
programming at least one less-significant-bit (LSB) page with padding data while programming the multi-bit per cell non-volatile memory with host data;
wherein the at least one LSB page is programmed in a manner such that a more-significant-bit (MSB) page corresponding to each LSB page programmed with host data of the same write command is programmed with host data.

2. The method of claim 1, wherein the multi-bit per cell non-volatile memory comprises a multi-bit per cell flash memory.

3. The method of claim 1, wherein the programming step comprises:
determining an LSB page number to denote an mount of the at least one LSB page programmed with padding data per write command, and a padding LSB page index to denote a beginning position of the at least one LSB page programmed with padding data per write command, according to information derived from the write command.

4. The method of claim 3, wherein the information of the write command comprises a length of the host data and a position of the host data.

5. The method of claim 1, wherein the at least one LSB page is programmed with dummy data.

6. The method of claim 1, wherein a portion of the at least one LSB page is programmed with old data to be garbage collected retrieved from the multi-bit per cell non-volatile memory.

7. The method of claim 1, further comprising:
receiving a stop write command; and
further programming at least one MSB page with padding data.

8. A system for programming a multi-bit per cell non-volatile memory with padding data, comprising:
a multi-bit per cell non-volatile memory; and
a controller disposed between a host and the multi-bit per cell non-volatile memory, the controller being configured to receive a write command with host data, and to program at least one less-significant-bit (LSB) page with padding data while programming the multi-bit per cell non-volatile memory with host data;
wherein the at least one LSB page is programmed in a manner such that an MSB page corresponding to each LSB page programmed with host data of the same write command is programmed with host data.

9. The system of claim 8, wherein the multi-bit per cell non-volatile memory comprises a multi-bit per cell flash memory.

10. The system of claim 8, wherein the controller comprises an interface electrically coupled to, and being communicating with, the host.

11. The system of claim 10, wherein the controller further comprises:
a buffer disposed between the interface and the multi-bit per cell non-volatile memory, the buffer being configured to temporarily store data while the data is being moved to or from the multi-bit per cell non-volatile memory.

12. The system of claim 8, wherein the controller comprises a dummy data generator configured to provide dummy data to be programming the at least one LSB page.

13. The system of claim 8, wherein the controller comprises an old data storage configured to store old data to be garbage collected retrieved from the multi-bit per cell non-volatile memory to be programming a portion of the at least one LSB page.
